(19) United States
(12) Patent Application Publication
(10) Pub. No.: US 2003/0194878 A1
(43) Pub. Date: Oct. 16, 2003

(54) Substrate processing apparatus and method

(75) Inventor: Katsuhiko Miya, Kyoto (JP)

Correspondence Address: OSTROLENK FABER GERB & SOFFEN, 1180 AVENUE OF THE AMERICAS, NEW YORK, NY, 100368403

(73) Assignee: Dainippon Screen Mfg. Co., Ltd.

(21) Appl. No.: 10/408,172

(22) Filed: Apr. 4, 2003

(30) Foreign Application Priority Data
Apr. 10, 2002 (JP) 2002-108047

(51) Int. Cl. H01L 21/302; H01L 21/461

(52) U.S. Cl. 438/745

(57) ABSTRACT

A substrate processing apparatus provided with a substrate rotating and holding mechanism for holding and rotating a substrate; and an etching liquid discharging mechanism disposed, on the axis of rotation of a substrate held and rotated by the substrate rotating and holding mechanism, at the side of the substrate rotating and holding mechanism with respect to the substrate. The etching liquid discharging mechanism has a discharge port arranged to discharge an etching liquid toward a position separated by 3 to 20 mm from the axis of rotation of the substrate as held and rotated by the substrate rotating and holding mechanism.

### BACKGROUND OF THE INVENTION

1. Field of the Invention

The present invention relates to substrate processing apparatus for and method of executing a surface treatment on a substrate by supplying an etching liquid thereto while the substrate is being rotated. Examples of a substrate to be treated include a variety of substrates such as a semiconductor wafer, a liquid-crystal-display-device glass substrate, a plasma-display-panel glass substrate, an optical-disk substrate, a magnetic-disk substrate, a magneto-optical-disk substrate, a photomask substrate and the like.

2. Description of Related Art

In production of semiconductor devices or liquid crystal display devices, there is used a substrate processing apparatus for executing a surface treatment on a substrate by supplying a treating liquid (a medical liquid or deionized water) to the substrate. For example, a substrate processing apparatus of the sheeting type for processing substrates one by one, is used for cleaning the surface of a substrate or for selectively etching (bevel etching) the peripheral edge of the substrate surface.

Such a sheeting-type substrate processing apparatus comprises, for example, a spin chuck for horizontally holding and rotating a substrate and a center shaft nozzle for supplying an etching liquid to the center of the backside of the substrate held by this spin chuck.

The spin chuck comprises, for example, a disk-like spin base, chuck pins standing from the peripheral edge of the spin base and arranged to come in contact with the end face of a substrate such that the substrate is held by and among the chuck pins, and a rotary shaft connected to the center of the backside of the spinbase. The rotary shaft is a perpendicularly extending hollow shaft, and the center shaft nozzle is disposed inside of the rotary shaft. According to this arrangement, an etching liquid can be supplied to the backside of the substrate while the space below the substrate backside is blocked from the ambient atmosphere by the spin base.

Thus, there can be executed an etching treatment on the backside of the substrate, or an etching treatment (bevel etching treatment) on the peripheral edge of the substrate surface with the use of an etching liquid reaching the substrate surface along the substrate end face from the substrate backside.

According to the arrangement above-mentioned, however, the etching liquid discharged from the center shaft nozzle is perpendicularly upwardly directed and strikes on the substrate at its axis of rotation. This causes the etching liquid to stay at the axis of rotation of the substrate backside. This results in faster or slower progress of an etching treatment on the substrate backside at its axis of rotation, as compared with other zones of the substrate. This is disadvantageous in view of etching uniformity.

There are instances where a metal thin film such as a copper thin film or the like is formed on the backside of a substrate such as a semiconductor wafer or the like, and this metal thin film is to be etched and removed with the use of an etching liquid (for example, a mixture liquid of a hydrochloric acid with a hydrogen peroxide solution, a mixture liquid of a hydrofluoric acid with a hydrogen peroxide solution, or a mixture liquid of a hydrofluoric acid with a nitric acid). In such a case, the etching proceeds faster on the substrate backside at its axis of rotation to which the etching liquid is directly and continuously applied.

On the other hand, there are instances where a polysilicon film, an amorphous silicon film, or a silicon oxide film formed on the backside of a substrate is to be etched and removed with a mixture liquid of a hydrofluoric acid with a nitric acid used as an etching liquid. In such a case, the etching proceeds slower on the substrate backside at its axis of rotation.

There are instances where an over-etching treatment is to be executed on the film as above-mentioned. In such a case, if the selectivity of the film to be etched and the grounding film is insufficient, the grounding film is undesirably etched only at its portion corresponding to the axis of rotation of the substrate backside, or at its portion corresponding to other zone than the axis of rotation of the substrate backside. This possibly contributes to a defect in a resulting semiconductor device or liquid crystal display device.

In a process in which a film to be treated is an oxide film and this oxide film is etched by a dilute hydrofluoric acid, the problem above-mentioned is less caused. However, when the substrate rotational speed is low, this causes the etching liquid to be slowly spread in the radial outward directions from the axis of rotation of the substrate. This is also disadvantageous in view of etching uniformity.

### SUMMARY OF THE INVENTION

It is an object of the present invention to provide substrate processing apparatus and method capable of improving the uniformity of etching on a substrate face.

A substrate processing apparatus according to the present invention comprises: a substrate rotating and holding mechanism for holding and rotating a substrate; and an etching liquid discharging mechanism which is disposed, on the axis of rotation of a substrate held and rotated by the substrate rotating and holding mechanism, at the side of the substrate rotating and holding mechanism with respect to the substrate, and which has a discharge port for discharging an etching liquid toward a position separated by 3 to 20 mm from the axis of rotation of the substrate as held and rotated by the substrate rotating and holding mechanism.

The substrate rotating and holding mechanism may be arranged to substantially horizontally hold and rotate a substrate. For example, the substrate rotating and holding mechanism may be rotated by itself while substantially horizontally holding a substrate.

The substrate rotating and holding mechanism may rotate a substrate as held from under, or may rotate a substrate as substantially horizontally held from above.

For example, when a substrate is horizontally held, the etching liquid discharging mechanism may discharge an etching liquid toward the top of the substrate, or may discharge an etching liquid toward the backside of the substrate.

Preferably, the etching liquid discharging mechanism is arranged such that an etching liquid discharged from the discharge port strikes against a position separated by 3˜20 mm from the axis of rotation of the substrate held by the substrate rotating and holding mechanism.

According to the present invention, an etching liquid discharged from the discharge port of the etching liquid discharging mechanism is not directed toward the axis of rotation of a substrate, but is discharged to its position separated by 3 to 20 mm from its axis of rotation. This always changes, according to the rotation of the substrate, the substrate position against which the etching liquid strikes. This results in progress of a uniform etching treatment on a substrate face (which may be the surface having devices formed thereon, or may be the backside) at its entire zone (the entire zone of the substrate face opposite to the discharge port of the etching liquid discharging mechanism).

Further, since the etching liquid strikes against a substrate at its position shifted from its axis of rotation, a centrifugal force quickly acts on the etching liquid. This causes the etching liquid to be quickly spread also on the substrate face. Accordingly, even though the substrate rotational speed is low, the entire zone of the substrate face can be processed substantially uniformly.

If the discharge port of the etching liquid discharging mechanism is arranged to discharge an etching liquid to a substrate at its position separated by less than 3 mm from its axis of rotation, this reduces the effect of improvement in the uniformity of the etching treatment. If the discharge port of the etching liquid discharging mechanism is arranged to discharge an etching liquid to a substrate at its position separated by more than 20 mm from its axis of rotation, this involves the likelihood that the etching liquid cannot be supplied to the axis of rotation of the substrate.

More specifically, when provision is made such that an etching liquid is discharged from the discharge port of the etching liquid discharging mechanism to a substrate at its position separated by 3 to 20 mm from its axis of rotation, the etching liquid can be supplied to the axis of rotation of the substrate by the spread of the etching liquid at the time when the same has reached the substrate face, and the etching liquid arrival position is remarkably changed, from time to time, due to the rotation of the substrate. This improves the uniformity of the etching treatment.

The etching liquid discharging mechanism may have only a single discharge port.

According to the arrangement above-mentioned, an etching liquid is discharged to a substrate face only from the single discharge port. This prevents the etching liquid from staying on the substrate face. This further improves the uniformity of the etching treatment. Further, only one discharge port is advantageous in that the etching liquid supply passage can not only be simplified in arrangement, but also be more easily sealed for preventing the etching liquid from leaking.

Further, when the rotary shaft of the substrate rotating and holding mechanism is a hollow shaft and the etching liquid supply passage is formed inside of this rotary shaft, it is sufficient to provide a single etching liquid supply passage. This advantageously makes the rotary shaft slender.

Preferably, the discharge port has a diameter of 8 mm or less.

According to the arrangement above-mentioned, an etching liquid can securely be supplied to a substrate at the desired position thereof.

For example, when processing a circular substrate (e.g., a semiconductor wafer) having a diameter of 200 mm, the discharge port preferably has a diameter of about 4 mm. When processing a circular substrate (e.g., a semiconductor wafer) having a diameter of 300 mm, the discharge port preferably has a diameter of about 4.5 mm.

It is preferable that the etching liquid discharging mechanism has an etching liquid supply passage extending to the discharge port, and that the etching liquid supply passage has a discharge tube portion which communicates with the discharge port and which is formed as inclined with respect to the axis of rotation of the substrate.

According to the arrangement above-mentioned, the discharge tube portion extending to the discharge port is inclined with respect to the axis of rotation of the substrate. Accordingly, when an etching liquid is to be discharged, for example from the stationary nozzle disposed on the axis of rotation of the substrate, to the substrate at its position separated by 3 to 20 mm from its axis of rotation, this stationary nozzle can be made in a compact design.

If the discharge tube portion is formed in parallel to the axis of rotation of the substrate, the etching liquid supply passage has to be bent twice when the etching liquid supply passage is formed on the axis of rotation of the substrate. On the other hand, when the discharge tube portion is formed as inclined with respect to the axis of rotation of the substrate, the etching liquid supply passage can be bent only once to discharge an etching liquid to the substrate at the desired position thereof. This facilitates machining the etching discharge nozzle.

Further, the etching liquid strikes against the substrate face from the direction inclined toward the radial outward direction of the substrate. This causes the etching liquid to be quickly spread on the substrate face. Accordingly, even though the substrate rotational speed is low, it can be expected to process the entire zone of the substrate face substantially uniformly.

When the etching liquid discharge nozzle is disposed on the axis of rotation of a substrate, the inclination angle of the discharge tube portion with respect to the axis of rotation is preferably set to about 20°. That is, the discharging direction of the etching liquid from the discharge port preferably forms about an angle of 20° with respect to the axis of rotation of the substrate.

Preferably, the substrate rotating and holding mechanism has an atmosphere blocking member opposite to the substrate for restricting the space between the substrate and the atmosphere blocking member.

According to the arrangement above-mentioned, an etching treatment can be executed on the substrate face with the space in the vicinity of the substrate face being restricted by the atmosphere blocking member. This advantageously improves the treatment quality.

When the atmosphere blocking member is disposed and it is intended to supply an etching liquid to the substrate face from the side of the substrate rotating and holding mechanism, it is inevitably required to supply the etching liquid to the substrate face from a position on the axis of rotation of the substrate. In such a case, when the etching liquid is discharged to the substrate face at its position separated by 3 to 20 mm from its axis of rotation, the etching treatment on the substrate face can be executed substantially uniformly.

The etching liquid discharging mechanism may comprise a stationary nozzle of which position with respect to the substrate rotating and holding mechanism remains unchanged. It is noted that the sentence of “the position with respect to the substrate rotating and holding mechanism remains unchanged”, is understood as comprising the case where the stationary nozzle is held in an irrotational state on its axis of rotation while the substrate rotating and holding mechanism is under rotation.

The substrate rotating and holding mechanism may have a hollow rotary shaft. In this case, the etching liquid discharging mechanism may comprise an etching liquid supply tube disposed as inserted inside of the rotary shaft for supplying an etching liquid to the stationary nozzle.

A substrate processing method according to the present invention comprises: a substrate holding and rotating step of holding and rotating a substrate by a substrate rotating and holding mechanism; and an etching liquid discharging step of discharging an etching liquid, from an etching liquid discharge port of an etching liquid discharging mechanism disposed on the axis of rotation of the substrate at the side of the substrate rotating and holding mechanism with respect to the substrate, toward the substrate at its position separated by 3 to 20 mm from its axis of rotation, the etching liquid discharging step being executed at the same time with the substrate holding and rotating step.

These and other features, objects, advantages and effects of the present invention will be more fully apparent from the following detailed description set forth below when taken in conjunction with the accompanying drawings.

### BRIEF DESCRIPTION OF THE DRAWINGS

FIG. 1 is a schematic section view illustrating the arrangement of a substrate processing apparatus according to an embodiment of the present invention;

FIG. 2 is a section view illustrating the arrangement of a spin chuck and its relevant rotational drive mechanism; and

FIG. 3 is a section view illustrating the arrangement of a stationary nozzle.

### DESCRIPTION OF THE PREFERRED EMBODIMENTS

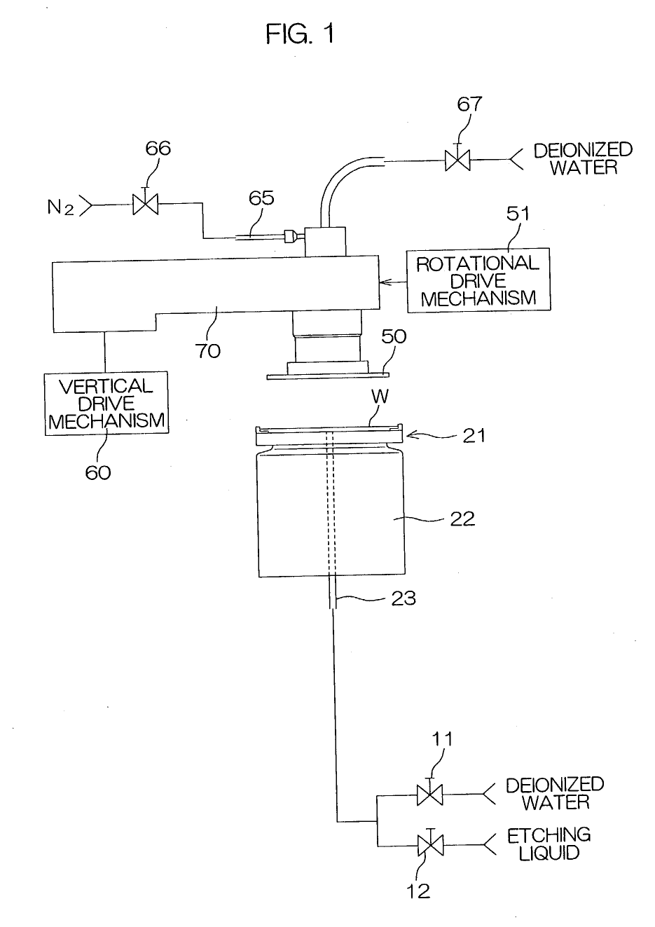

FIG. 1 is a schematic section view illustrating the arrangement of a substrate processing apparatus according to an embodiment of the present invention. This substrate processing apparatus is arranged to remove, at the same time, both a thin film formed on the backside of a semiconductor wafer (hereinafter referred to simply as wafer) W as an example of a substrate, and a thin film formed on the peripheral edge portion of the wafer W surface and on the end face of the wafer W. The substrate processing apparatus is provided in a processing cup (not shown) thereof with a spin chuck 21 arranged to substantially horizontally hold a wafer W with its backside turned down and also arranged to be rotated around the perpendicular axis of rotation substantially passing through the center of the wafer W thus held.

The spin chuck 21 is to be rotated as connected to the drive shaft of a motor 22 serving as a rotational drive mechanism. The drive shaft of the motor 22 is a hollow shaft inside of which there passes a treating liquid supply tube 23 in the form of a center shaft nozzle capable of supplying deionized water or an etching liquid. The treating liquid supply tube 23 is connected to a stationary nozzle having a discharge port in the vicinity of the center of the backside of the wafer W held by the spin chuck 21. Deionized water or an etching liquid is to be supplied from this discharge port toward the backside of the wafer W.

Deionized water or an etching liquid is to be supplied, at predetermined timings, to the treating liquid supply tube 23 through a deionized water supply valve 11 connected to a deionized water supply source or an etching liquid supply valve 12 connected to an etching liquid supply source.

There is used an etching liquid of the type suitable for the type of a thin film to be removed from a wafer W face (top side or backside). For example, when removing a metal film such as a copper thin film or the like from the wafer W backside or the like, there is for example used, as an etching liquid, a mixture liquid of a hydrochloric acid with a hydrogen peroxide solution, a mixture liquid of a hydrofluoric acid with a hydrogen peroxide solution, or a mixture liquid of a hydrofluoric acid with a nitric acid. When removing a polysilicon film, an amorphous silicon film, or a silicon oxide film from a wafer W, there is for example used, as an etching liquid, a mixture liquid of a hydrofluoric acid with a nitric acid. Further, when removing an oxide film on a wafer W, a dilute hydrofluoric acid is for example used as an etching liquid.

Horizontally disposed above the spin chuck 21 is a disk-like blocking plate 50 opposite to the wafer W held by the spin chuck 21. This blocking plate 50 has such sizes as to cover substantially the whole zone of the wafer W top, and is attached, in a manner rotatable around the perpendicular axis of rotation, to the vicinity of the tip of an arm 70 connected to a vertical drive mechanism 60.

The blocking plate 50 is vertically movable with respect to the spin chuck 21 by the vertical drive mechanism 60. By a rotational drive mechanism 51, the blocking plate 50 is rotatable around the axis of rotation identical with that of the spin chuck 21. Provision is made such that a nitrogen gas as an inert gas is discharged into the space between the blocking plate 50 and the wafer W. The nitrogen gas is guided to a nitrogen gas discharge port (not shown) in the vicinity of the center of the backside of the blocking plate 50 from a nitrogen gas supply valve 66 through a nitrogen gas supply tube 65. As necessary, deionized water from a deionized water supply valve 67 can be supplied to the top of the wafer W through a nozzle disposed at the center of the backside of the blocking plate 50.

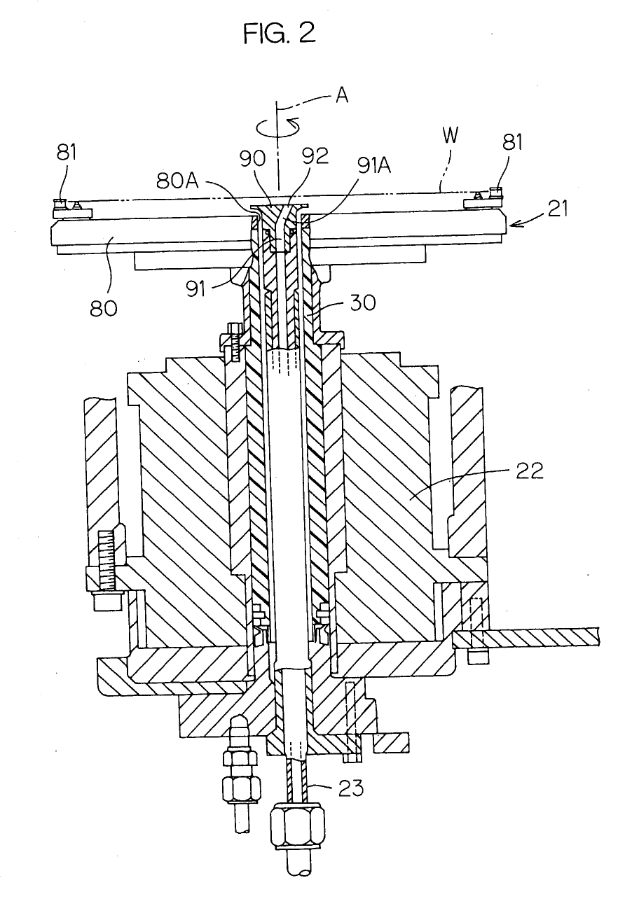

FIG. 2 is a section view illustrating the arrangement of the spin chuck 21 and its relevant rotational drive mechanism. The spin chuck 21 has a disk-like spin base 80, and a perpendicularly extending rotary shaft 30 of the motor 22 is connected to the backside of the spin base 80. As mentioned earlier, this rotary shaft 30 is a hollow shaft, in and through which the treating liquid supply tube 23 passes.

Formed in the axis of rotation of the spin base 80 is a through-hole 80A in which inserted is a stationary nozzle 90 of which position with respect to the spin chuck 21 remains unchanged. This stationary nozzle 90 is connected and fixed to the upper end of the treating liquid supply tube 23.

The spin chuck 21 has the spin base 80 and holding members 81 disposed at the peripheral edge thereof and arranged to hold and support both the peripheral end face of a wafer W and the peripheral edge of the wafer W backside. The holding members 81 are disposed in plural number (for example, three) at the peripheral edge of the spin base 80 at spatial intervals along the peripheral direction thereof.

According to the arrangement above-mentioned, when executing a processing on a wafer W, the wafer W is held by and between the holding members 81 of the spin chuck 21, and the spin base 80 is rotated around the perpendicularly extending axis of rotation A by rotationally driving the hollow rotary shaft 30 by the motor 22. This causes the wafer W to be rotated at a fixed speed around the axis of rotation A.

At this time, the treating liquid supply tube 23 and the stationary nozzle 90 remain stationary with a predetermined clearance held between the treating liquid supply tube 23 and the inner wall of the rotary shaft 30 and between the stationary nozzle 90 and the inner wall of the through-hole 80A or the like of the spin base 80.

Then, when the etching liquid supply valve 12 is opened to supply the etching liquid to the treating liquid supply tube 23, the etching liquid is supplied to the backside of the wafer under rotation. Under the action of a centrifugal force generated by the rotation of the wafer W, this etching liquid is guided, along the backside of the wafer W, in the wafer radial outward direction, and then goes round the peripheral end face of the wafer W and reaches the peripheral edge portion of the wafer W surface.

Thus, it is possible to remove an unnecessary thin film (metal film, polysilicon film, oxide film or the like) on the wafer W backside, and it is also possible to remove an unnecessary thin film on the peripheral end face of the wafer W and the peripheral edge portion of the wafer W surface. At the time of etching treatment, the spin base 80 intercepts the wafer W backside from the ambient atmosphere, thus contributing to improvement in etching treatment quality.

When the etching treatment is finished in the manner above-mentioned, the etching liquid supply valve 12 is closed and the deionized water supply valve 11 is in turn opened. Then, deionized water is guided from the treating liquid supply tube 23 to the stationary nozzle 90, and then supplied to the wafer W backside. Under the action of a centrifugal force generated by the rotation of the wafer W, this deionized water is spread in the wafer radial outward direction, and then reaches the peripheral edge portion of the wafer W surface through the peripheral end face of the wafer W. Thus, the etching liquid stuck to the wafer W is washed away.

Then, the deionized water supply valve 11 is closed, and the rotary shaft 30 is rotated at high speed by the motor 22. This executes a shaking-off drying processing to remove the moisture stuck to the wafer W surface and backside.

While the etching liquid or deionized water is being supplied to the wafer W, the blocking plate 50 is lowered to a position in close vicinity to the wafer W, and nitrogen gas is blown toward the top of the wafer W from the vicinity of the center of the blocking plate 50. This prevents the etching liquid from reaching the wafer W center zone (device forming zone). The etching treatment can therefore be selectively executed only on the zone having a predetermined width at the peripheral portion of the wafer W surface.

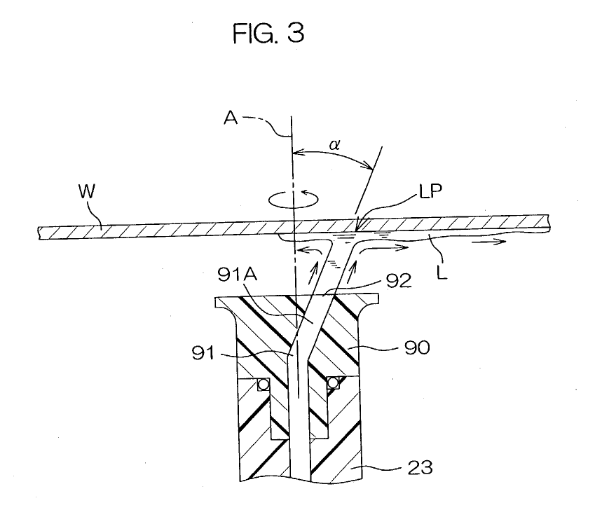

FIG. 3 is a section view illustrating the arrangement of the stationary nozzle 90. The stationary nozzle 90 incorporates a treating liquid supply passage 91 through which there passes a treating liquid from the treating liquid supply tube 23. This treating liquid supply passage 91 has a treating liquid discharge tube or passage portion 91A inclined by a predetermined angle a (about 20° in this embodiment) with respect to the axis of rotation A of the wafer W. The treating liquid discharge tube portion 91A is provided at its exit with a discharge port 92, of which diameter is for example about 4 mm.

A treating liquid L guided from the treating liquid supply tube 23 to the treating liquid supply passage 91 of the stationary nozzle 90, passes through the inclined treating liquid discharge tube portion 91A, and is therefore discharged in the direction forming an angle of about 20° with respect to the axis of rotation A of the wafer W. More specifically, the treating liquid L is guided, from the direction forming an angle of about 20° with respect to the axis of rotation A of the wafer W, to the wafer W backside. As a result, the liquid arrival position LP of the treating liquid L on the wafer W backside, is shifted by a predetermined distance (for example about 5 mm) from the axis of rotation A of the wafer W.

The treating liquid L striking against the wafer W backside, spreads along the wafer W backside and is guided in the wafer radial outward direction under the action of a centrifugal force generated by the rotation of the wafer W.

The liquid arrival position LP of the treating liquid L is shifted from the axis of rotation of the wafer W. Accordingly, the collision position of the treating liquid L from the stationary nozzle 90 with the wafer W backside, is changed, from time to time, due to the rotation of the wafer W. On the other hand, since the treating liquid L spreads at the time of its collision with the wafer W backside, the treating liquid L is supplied also to the axis of rotation of the wafer W. By executing an etching treatment on the wafer W under such circumferences, a uniform etching treatment can be executed throughout the wafer W face (in particular, its backside).

Further, since the liquid arrival position LP is shifted from the axis of rotation of the wafer W and the treating liquid L strikes against the wafer W backside from the radially outwardly inclined direction, the treating liquid L rapidly spreads throughout the wafer W backside. Accordingly, even though the wafer W rotational speed is low, the processing on the wafer W backside can uniformly be executed.

In the foregoing, an embodiment of the present invention has been discussed, but the present invention may also be embodied in other manner. For example, the embodiment above-mentioned is arranged such that the treating liquid L discharged from the stationary nozzle 90 comes in collision with the wafer W backside at its position shifted by about 5 mm from its axis of rotation A. However, similar effects may also be produced as far as provision is made such that the treating liquid L comes in collision with the wafer W backside at its position shifted by 3 to 20 mm from its axis of rotation.

In the embodiment above-mentioned, the discharge port 92 has a diameter of about 4 mm, but this diameter value is suitable for processing a wafer W having a diameter of 200 mm. For processing a wafer W having a diameter of 300 mm, the diameter of the discharge port 92 is preferably set to about 4.5 mm. Generally, the diameter of the discharge port 92 may be set to 8 mm or less such that the conditions for executing a satisfactory etching treatment are satisfied.

In the embodiment above-mentioned, the description has been made of the substrate processing apparatus in which a wafer W is held from under and an etching liquid is supplied to the wafer W backside. However, the present invention may also be applied to the arrangement in which a wafer W is held from above and a treating liquid is supplied to the top of the wafer W.

Further, a wafer W is not necessarily held horizontally, but may be held vertically or inclinedly.

In the embodiment above-mentioned, the description has been made of the substrate processing apparatus in which an etching treatment is executed on a disk-like substrate serving as a semiconductor wafer. However, the present invention may also be applied to the arrangement in which an etching treatment is executed on a quadrilateral substrate such as a liquid-crystal-display glass substrate, a plasma-display glass substrate or the like.

Embodiments of the present invention have been discussed in detail, but these embodiments are mere specific examples for clarifying the technical contents of the present invention. Therefore, the present invention should not be construed as limited to these specific examples. The spirit and scope of the present invention are limited only by the appended claims.

This Application corresponds to Japanese Patent Application Serial No. 2002-108047 filed on Apr. 10, 2002 with Japanese Patent Office, the disclosure of which is incorporated herein by reference.

What we claim is:

1. A substrate processing apparatus, comprising:
a substrate rotating and holding mechanism for holding and rotating a substrate; and
an etching liquid discharging mechanism which is disposed, on an axis of rotation of a substrate held and rotated by the substrate rotating and holding mechanism, at a side of the substrate rotating and holding mechanism with respect to the substrate, and which has a discharge port for discharging an etching liquid toward a position separated by 3 to 20 mm from the axis of rotation of the substrate as held and rotated by the substrate rotating and holding mechanism.

2. A substrate processing apparatus according to claim 1, wherein the etching liquid discharging mechanism has only a single discharge port.

3. A substrate processing apparatus according to claim 1, wherein the discharge port has a diameter of 8 mm or less.

4. A substrate processing apparatus according to claim 1, wherein the etching liquid discharging mechanism has an etching liquid supply passage extending to the discharge port, and the etching liquid supply passage has a discharge tube portion which communicates with the discharge port and which is formed as inclined with respect to the axis of rotation of the substrate.

5. A substrate processing apparatus according to claim 1, wherein the substrate rotating and holding mechanism has an atmosphere blocking member opposite to the substrate for restricting a space between the substrate and the atmosphere blocking plate.

6. A substrate processing apparatus according to claim 1, wherein the etching liquid discharging mechanism includes a stationary nozzle of which position with respect to the substrate rotating and holding mechanism remains unchanged.

7. A substrate processing apparatus according to claim 1, wherein
the substrate rotating and holding mechanism has a hollow rotary shaft, and
the etching liquid discharging mechanism includes an etching liquid supply tube disposed as inserted inside of the rotary shaft for supplying an etching liquid to the stationary nozzle.

8. A substrate processing method, comprising:
a substrate holding and rotating step of holding and rotating a substrate by a substrate rotating and holding mechanism; and
an etching liquid discharging step of discharging an etching liquid, from an etching liquid discharge port of an etching liquid discharging mechanism disposed on an axis of rotation of the substrate at a side of the substrate rotating and holding mechanism with respect to the substrate, toward the substrate at its position separated by 3 to 20 mm from its axis of rotation,
the etching liquid discharging step being executed at the same time with the substrate holding and rotating step.

9. A substrate processing method according to claim 8, wherein at the etching liquid discharging step, an etching liquid is discharged toward the substrate from only a single discharge port from the side of the substrate rotating and holding mechanism.

10. A substrate processing method according to claim 8, wherein the etching liquid discharging step includes a step of discharging an etching liquid from the discharge port having a diameter of 8 mm or less.

11. A substrate processing method according to claim 8, wherein the etching liquid discharging step includes a step of discharging an etching liquid, from the etching liquid discharge port, to the direction inclined with respect to the axis of rotation of the substrate.

12. A substrate processing method according to claim 8, further comprising a step of restricting, by an atmosphere blocking plate disposed at the substrate rotating and holding mechanism, a space on the substrate at the side of the substrate rotating and holding mechanism.

13. A substrate processing method according to claim 8, wherein the etching liquid discharging step includes a step of supplying an etching liquid from a discharge port of a stationary nozzle of which position with respect to the substrate rotating and holding mechanism remains unchanged.

14. A substrate processing method according to claim 8, wherein
the substrate rotating and holding mechanism has a hollow rotary shaft, and
the etching liquid discharging step includes a step of supplying an etching liquid, to the discharge port, from an etching liquid supply tube disposed as inserted inside of the rotary shaft for supplying the etching liquid to the stationary nozzle.
